(19) United States
(12) Patent Application Publication
(10) Pub. No.: US 2021/0234146 A1
(43) Pub. Date: Jul. 29, 2021

(54) PROCESS FOR AT LEAST PARTIALLY COATING REDOX-ACTIVE MATERIALS

(71) Applicant: BASF SE, Ludwigshafen am Rhein (DE)

(72) Inventors: Jose A JIMENEZ, Union, NJ (US); Robert PRUNCHAK, Union, NJ (US)

(73) Assignee: BASF SE, Ludwigshafen am Rhein (DE)

(21) Appl. No.: 15/734,700

(22) PCT Filed: May 29, 2019
(86) PCT No.: PCT/EP2019/064059

§ 371 Date: Dec. 3, 2020

(30) Foreign Application Priority Data
Jun. 6, 2018 (EP) 18176274.1

(51) Int. Cl. H01M 4/04; C23C 16/442; H01M 4/36; C23C 16/44; C23C 16/56; H01M 4/505; H01M 4/525

(52) U.S. Cl. CPC H01M 4/0402; C23C 16/442; H01M 4/366; H01M 4/525; C23C 16/56; H01M 4/505; C23C 16/4417

(57) ABSTRACT

Process for making an at least partially coated redox-active material wherein said process comprises the following steps: (a) Treating a redox-active material with a metal alkoxide or metal halide or metal amide or alkyl metal compound, wherein said redox-active material contains at least one metal selected from V, Cr, Mn, Fe, Co, Ni, Ag, Cu, Mo, W, Sn, Sb, Te, Pb, Bi and rare earth metals in an oxidized state, (b) Treating the material obtained in step (a) with anoxidizing agent, (c) Repeating the sequence of steps (a) and (b) from one to 100 times, wherein the average thickness of the resulting coating is in the range of from 0.1 to 50 nm.

The present invention is directed towards a process for making an at least partially coated redox-active material wherein said process comprises the following steps:
(a) Treating a redox-active material with a metal alkoxide or metal halide or metal amide or alkyl metal compound, wherein said redox-active material contains at least one metal, preferably at least two different metals selected from V, Cr, Mn, Fe, Co, Ni, Ag, Cu, Mo, W, Sn, Sb, Te, Pb, Bi and rare earth metals in an oxidized state,
(b) treating the material obtained in step (a) with an oxidizing agent,
(c) repeating the sequence of steps (a) and (b) from one to 100 times,

wherein the average thickness of the resulting coating is in the range of from 0.1 to 50 nm.

Atomic layer deposition (ALD) is a chemical vapor coating technique considered valuable for depositing thin films (e.g. as protective barriers) for a wide-range of applications such as heterogeneous catalysis and electrochemical energy storage, e.g., U.S. Pat. No. 9,196,901. It is often the case in the context of the applications of the finished materials that the substrates to be coated contain oxide materials comprising metal ions in an oxidized state essential for the respective application. However, the existence of higher valence states of the metals also implies that the materials are susceptible to undesired redox chemistry during the coating process that can be damaging to their performance. Moreover, common precursors utilized in ALD possess significant reducing agent character which can alter the chemical and structural properties of the redox-active material to be coated [e.g. B. Xiao, et al., Nano Energy 34 (2017) 120-130].

Significant reduction of the metal ions by the ALD precursor could indeed be detrimental to the application. This problem develops especially for when the coating technology is applied to particle surfaces in powders. For instance, if the material is a Ni-containing cathode active material for Li ion batteries some Ni³⁺ may be reduced to Ni²⁺ the resultant cathode active material becomes prone to the Ni²⁺/Li⁺ cation mixing harmful to battery performance. Furthermore, on Bi³⁺-based pigments it may be observed that that the color of the powder deteriorates upon a few cycles of trimethylaluminum (TMA) and H₂O intended to deposit a protective alumina film.

Early hints at redox-active material reduction by a compound such as trimethyl aluminum frequently used during a coating process becomes evident through real-time mass spectrometry measurements wherein atypical gas-phase products are generated primarily for the first ALD cycle.

In the case of particle objects with relatively high surface areas, additional problems arise wherein surface properties altered by the coating process can also lead to undesirable effects on powder behavior. Especially in embodiments wherein the particles have a tendency to agglomerate the efficiency of the coating process leaves room for improvement both in respect to reaction time and percentage of covered particles.

It was therefore an objective of the present invention to provide a process by which redox-active materials may be coated to decrease the degree of chemical reduction of the oxidized metals by the process and further improve coated powder characteristics.

Accordingly, the process as defined at the outset has been found, hereinafter also referred to as inventive process or as process according to the (present) invention. The inventive process is a process for making an at least partially coated redox-active material.

The term “partially coated” as used in the context with the present invention refers to at least 80% of the particles of a batch of particulate material being coated, and to at least 50% of the surface of each particle being coated, for example 75 to 99.99% and preferably 80 to 90%.

The thickness of such coating may be very low, for example 0.1 to 5 nm. In other embodiments, the thickness may be in the range of from 6 to 15 nm. In further embodiments, the thickness of such coating is in the range of from 16 to 50 nm. The thickness in this context refers to an average thickness determined mathematically by calculating the amount of thickness per particle surface and assuming a 100% conversion.

Without wishing to be bound by any theory, it is believed that non-coated parts of particles do not react due to specific chemical properties of the particles, for example density of chemically reactive groups such as, but not limited to hydroxyl groups, oxide moieties with chemical constraint, or to adsorbed water.

In one embodiment of the present invention, the redox-active material has an average particle diameter (D50) in the range of from 0.2 to 20 μm. In a preferred embodiment, the redox-active material has an average particle diameter (D50) in the range of from 0.2 to 10 μm, preferably from 0.5 to 5 μm. In another preferred embodiment of the present invention the redox-active material has an average particle diameter (D50) in the range of from 3 to 20 μm, more preferably from 5 to 16 pm. The average particle diameter can be determined, e. g., by light scattering or LASER diffraction or electroacoustic spectroscopy. The particles are usually composed of agglomerates from primary particles, and the above particle diameter refers to the secondary particle diameter.

In one embodiment of the present invention, the redox-active material has a specific surface (BET), hereinafter also referred to as “BET surface”, in the range of from 0.1 to 10 m²/g, preferably 0.1 to 3.5 m²/g and even more preferably from 0.2 to 0.5 m²/g. In another preferred embodiment of the present invention the redox-active material has a BET surface in the range from 0.1 to 100 m²/g, preferably 1 to 50 m²/g and even more preferably from 2 to 10 m²/g. The BET surface may be determined by nitrogen adsorption after outgassing of the sample at 200° C. for 30 minutes or more and beyond this accordance with DIN ISO 9277:2010.

The inventive process comprises two steps (a) and (b), in the context of the present invention also referred to as step (a) and step (b).

Step (a) includes treating the given redox-active material with a metal alkoxide or metal halide or metal amide or alkyl metal compound. Said redox-active material contains at least one metal selected from V, Cr, Mn, Fe, Co, Ni, Ag, Cu, Mo, W, Sn, Sb, Te, Pb, Bi and rare earth metals, preferably at least two different metal ions selected from V, Cr, Mn, Fe, Co, Ni, Ag, Cu, Mo, W, Sn, Sb, Te, Pb, Bi and rare earth metals, in each case in an oxidized state. Examples of the above are inorganic pigments based on iron-based magnetic materials, phosphors for light emitting diodes, mixed metal oxides employed as chemical and environmental catalysts, and cathode active materials for Li ion batteries with general formula Li₁₊ₓTM₁₋ₓO₂, wherein TM is a combination of Ni, Co and, optionally, Mn, and, optionally, at least one metal selected from Al, Ti, Mo, W, and Zr, and x is in the range of from zero to 0.2.

Examples of the latter category are Li₍₁₊ₓ₎[Ni_{0.6}Co_{0.2}Mn_{0.2}]₍₁₋ₓ₎O₂, Li₍₁₊ₓ₎[Ni_{0.7}Co_{0.2}Mn_{0.1}]₍₁₋ₓ₎O₂, Li₍₁₊ₓ₎[Ni_{0.8}Co_{0.1}Mn_{0.1}]₍₁₋ₓ₎O₂, and Li₍₁₊ₓ₎[Ni_{0.85}Co_{0.10}Mn_{0.05}]₍₁₋ₓ₎O₂ each with x as defined above.

Examples of phosphors are white phosphors, especially mixtures from zinc cadmium sulfide and zinc sulfide silver, sometimes also denoted as ZnS:Ag+(Zn,Cd)S:Ag, quantum dots (QDs), lead perovskites, red phosphors, especially yttrium oxide-sulfide doped with europium, yellow phosphors, especially (Zn,Cd)S:Ag, Ce-doped yttrium aluminium garnet (YAG), green phosphors, especially zinc sulfide combined with Cu, denoted as ZnS:Cu, and blue phosphors, especially ZnS:Ag.

In a preferred embodiment, step (a) is carried out in combination with the flow of an inert gas during the treatment. Examples of inert gases include argon and nitrogen. Without wishing to be bound by any theory, it is believed that the inert carrier gas dilutes the concentration of metal alkoxide or metal halide or metal amide or alkyl metal compound. Hence, increasing the inert gas flow rate during the exposure of redox-active material to said precursors has been found to be beneficial for conserving the properties of pristine material.

In one embodiment of the inventive process, step (a) is performed at a temperature in the range of from 15 to 1000° C., preferably 15 to 500° C., more preferably 20 to 350° C., and even more preferably 50 to 200° C. It is preferred to select a temperature in step (a) at which metal alkoxide or metal halide or metal amide or alkyl metal compound, as the case may be, is thermally stable in the gas phase.

In one embodiment of the present invention, step (a) is carried out at normal pressure but step (a) may as well be carried out at reduced or elevated pressure. For example, step (a) may be carried out at a pressure in the range of from 5 mbar to 1 bar above normal pressure, preferably 10 to 150 mbar above normal pressure. In the context of the present invention, normal pressure is 1 atm or 1013 mbar. In other embodiments, step (a) may be carried out at a pressure in the range of from 150 mbar to 560 mbar above normal pressure. In other embodiments, step (a) is carried out at a pressure of 999 to 1 mbar below normal pressure.

In a preferred embodiment of the present invention, alkyl metal compound or metal alkoxide or metal amide, respectively, is selected from Al(R¹)₃, Al(R¹)₂OH, AlR¹(OH)₂, M¹(R¹)_{4-y}H_{y}, Al(OR²)₃, Zn(R¹)₂, M¹(OR²)₂, M¹(OR²)₄, M¹[NR²)₂]₄, M¹H[NR²)₂]₃, and methyl alumoxane, wherein

R¹ are different or equal and selected from C₁-C₈-alkyl, straight-chain or branched,

R² are different or equal and selected from C₁-C₄-alkyl, straight-chain or branched,

M¹ is Ti, Hf, Si or Zr, with Ti being preferred,

Metal alkoxides may be selected from C₁-C₄-alkoxides of aluminum, and transition metals. Preferred transition metals are titanium and zirconium. Examples of alkoxides are methanolates, hereinafter also referred to as methoxides, ethanolates, hereinafter also referred to as ethoxides, propanolates, hereinafter also referred to as propoxides, and butanolates, hereinafter also referred to as butoxides. Specific examples of propoxides are n-propoxides and iso-propoxides. Specific examples of butoxides are n-butoxides, iso-butoxides, sec-butoxides and tert-butoxides. Combinations of alkoxides are feasible as well.

Preferred examples of metal C₁-C₄-alkoxides are Ti[OCH(CH₃)₂]₄, Ti(OC₄H₉)₄, Zn(OC₃H₇)₂, Zr(OC₄H₉)₄, Zr(OC₂H₅)₄, Al(OCH₃)₃, Al(OC₂H₅)₃, Al(O-n-C₃H₇)₃, Al(O-iso-C₃H₇)₃, Al(O-sec-C₄H₉)₃, and Al(OC₂H₅)(O-sec-C₄H₉)₂.

Preferred examples of halides are TiCl₄, TiOCl₂, ZrCl₄, ZrOCl₂, HfCl₄, HfOCl₂, SiCl₄, (CH₃)₃SiCl, CH₃SiCl₃, ZnCl₂.

Metal amides are sometimes also referred to as metal imides. Examples of metal amides are Ti[N(CH₃)₂]₄, Zr[N(C₂H₅)₂]₄, Zr[N(CH₃)₂]₄, Zr[(CH₃)N(C₂H₅)]₄, Hf[N(CH₃)₂]₄, and SiH[N(CH₃)₂]₃.

Examples of aluminum alkyl compounds are trimethyl aluminum, triethyl aluminum, triisobutyl aluminum, diethyl zinc, dimethylzinc, and methyl alumoxane. Examples of methyl alumoxane are partially hydrolyzed trimethylaluminum types including compounds of the general stoichiometry Al(CH₃)₂OH and Al(CH₃)(OH)₂.

Particularly preferred compounds are selected from metal C₁-C₄-alkoxides and metal alkyl compounds, and even more preferred are titanium isopropoxide and trimethylaluminum.

In one embodiment of the present invention, the amount of metal alkoxide or metal halide or metal amide or alkyl metal compound is in the range of 0.1 to 1 g/kg particular material.

Preferably, the amount of metal alkoxide or metal amide or alkyl metal compound, respectively, is calculated to amount to 80 to 200% of a monomolecular layer on the particular material per cycle.

In one embodiment of the present invention, step (a) is performed in a rotary kiln, in a free fall mixer, in a continuous vibrating bed or a fluidized bed. Step (a) of the inventive process as well as step (b)—that will be discussed in more detail below—may be carried out in the same or in different vessels.

In a preferred embodiment of the present invention, the duration of step (a) is in the range of from 1 second to 2 hours, preferably 1 second up to 45 minutes.

In a second step, in the context of the present invention also referred to as step (b), the material obtained in step (a) is treated with an oxidizing agent. It is preferred that in step (b) no humidity is applied.

In an embodiment of the present invention, oxidizing agents in step (b) are selected from species with a positive standard reduction potential, that means, E°≥0 V. Preferred examples are oxygen, peroxides and ozone. Examples of peroxides are hydrogen peroxide and organic peroxides such as tert-butyl peroxide.

Ozone may be generated from oxygen under conditions known per se, and therefore, in step (b) ozone usually is applied in the presence of oxygen. During the application of ozone in step (b) it is preferred that no inert gas is present.

In one embodiment of the present invention, step (b) is carried out at a temperature in the range of from 50 to 250° C.

In one embodiment of the present invention, step (b) is performed in a rotary kiln, in a free fall mixer, in a continuous vibrating bed or a fluidized bed.

In one embodiment of the present invention, step (b) is carried out at normal pressure but step (b) may as well be carried out at reduced or elevated pressure. For example, step (b) may be carried out at a pressure in the range of from 5 mbar to 1 bar above normal pressure, preferably 10 to 250 mbar above normal pressure. In the context of the present invention, normal pressure is 1 atm or 1013 mbar. In other embodiments, step (b) may be carried out at a pressure in the range of from 150 mbar to 560 mbar above normal pressure. In other embodiments, step (b) is carried out at a pressure of 999 to 1 mbar below normal pressure.

Steps (a) and (b) may be carried out at the same pressure or at different pressures, preferred is at the same pressure.

In a preferred embodiment of the present invention, the duration of step (b) is in the range of from 1 second to 2 hours, preferably 1 second up to 45 minutes.

In one embodiment of the present invention, the reactor in which the inventive process is carried out is flushed or purged with an inert gas between steps (a) and (b), for example with dry nitrogen or with dry argon. Suitable flushing—or purging—times are 1 second to 60 minutes. It is preferred that the amount of inert gas is sufficient to exchange the contents of the reactor of from one to 15 times. Said flushing also takes place after step (b), thus before another step (a).

In one embodiment of the present invention, each purging step between (a) and (b) has a duration in the range of from one second to fifteen minutes.

Each of steps (a) and (b) may be carried out in a fixed bed reactor, in a fluidized bed reactor, in a forced flow reactor or in a mixer, for example in a compulsory mixer or in a free-fall mixer. Examples of fluidized bed reactors are spouted bed reactors. Examples of compulsory mixers are ploughshare mixers, paddle mixers and shovel mixers. Preferred are ploughshare mixers. Preferred ploughshare mixers are installed horizontally, the term horizontal referring to the axis around which the mixing element rotates. Preferably, the inventive process is carried out in a shovel mixing tool, in a paddle mixing tool, in a Becker blade mixing tool and, most preferably, in a ploughshare mixer in accordance with the hurling and whirling principle. Free fall mixers are using the gravitational force to achieve mixing. In a preferred embodiment, steps (a) and (b) of the inventive process are carried out in a drum or pipe-shaped vessel that rotates around its horizontal axis. In a more preferred embodiment, steps (a) and (b) of the inventive process are carried out in a rotating vessel that has baffles.

In one embodiment of the present invention, the rotating vessel has in the range of from 2 to 100 baffles, preferably 2 to 20 baffles. Such baffles are preferably flush mount with respect to the vessel wall.

In one embodiment of the present invention, such baffles are axially symmetrically arranged along the rotating vessel, drum, or pipe. The angle with the wall of said rotating vessel is in the range of from 5 to 45°, preferably 10 to 20°. By such arrangement, they can transport coated redox-active material very efficiently through the rotating vessel.

In one embodiment of the present invention, said baffles reach in the range of from 10 to 30% into the rotating vessel, referring to the diameter.

In one embodiment of the present invention, said baffles cover in the range of from 10 to 100%, preferably 30 to 80% of the entire length of the rotating vessel. In this context, the term length is parallel to the axis of rotation.

In a preferred embodiment of the present invention the inventive process comprises the step of removing the coated material from the vessel or vessels, respectively, by pneumatic conveying, e.g. 20 to 100 m/s.

Step (c) includes repeating the sequence of steps (a) and (b) from one to 100 times, preferred are wise to 50 repetitions.

Repetition may include repeating a sequence of steps (a) and (b) each time under exactly the same conditions or under modified conditions but still within the range of the above definitions. For example, each step (a) may be performed under exactly the same conditions, or, e.g., each step (a) may be performed under different temperature conditions or with a different duration, for example 120° C., then 140° C. and 160° C. each from 1 second to 1 hour.

By performing the inventive process, at least partially coated redox-active materials are obtained. They show excellent properties. For example, colored at least partially coated redox-active materials obtained according to the inventive process show excellent color stability in combination alkaline environments.

The inventive process may be modified by additional steps that are optional.

In an optional step (d), a pre-treatment is performed before the first performance of step (a). Such pre-treatment may include heating the particulate redox-active material between 100 to 300° C., for example for 15 minutes up to 5 hours under inert gas. In a preferred embodiment step (d) includes a chemical pretreatment wherein the substrate is subjected to a reducing atmosphere together with heating under a gas mixture containing a reducing gas with an inert gas. Examples of reducing gases are H₂ and CO. Examples of inert gases include argon and nitrogen. Without wishing to be bound by any theory, it is believed that the reducing atmosphere treatment provides for a controlled reduction of the surface of the redox-active particulate material thereby rendering the particles less reactive towards the metal precursor from step (a).

Step (d) may be performed in a rotary kiln or a fluidized bed reactor. In special embodiments, step (d) may be performed in the same vessel as step (a).

Another—optional—step is a post-treatment (e) performed by heating the material obtained after the last step (c) at a temperature from 150 to 600° C. Preferred are 200 to 500° C., and even more preferably, from 250 to 400° C.

In one embodiment of the present invention, step (e) is carried out in an atmosphere of inert gas, for example nitrogen or a noble gas such as argon. Preferably, such inert gas has a water content in the range of from 0.2 to 10 ppm, preferably 0.2 to 5 ppm, and a carbon dioxide content ion the range of from 0.1 to 10 ppm. The CO₂ content may be determined by, e.g., optical methods using infrared light.

In a preferred embodiment step (e) is carried out in an oxygen-rich atmosphere, for example air, pure oxygen or oxygen-enriched air.

In one embodiment of the present invention, step (e) has a duration in the range of from 10 seconds to 2 hours, preferred are 10 minutes to 2 hours.

In another embodiment, step (e) is carried out at normal pressure.

Step (e) may be performed in a rotary kiln or a fluidized bed reactor. In special embodiments, step (e) may be performed in the same vessel as step (b).

By such optional steps, the performance of the redox-active materials may be further improved.

The invention is further illustrated by working examples.

General remarks: sccm: standard cubic centimeters per minute, cubic centimeters under standard conditions: 25° C., 1 atm.

ICP-OES: Inductively coupled plasma optical emission spectroscopy

C-PIG.1: BiVO₄ in the form of yellow granules, with a BET surface of 8 m²/g, density 7.5 g/cm³, an average particle diameter (D50) of 0.5 μm and a bulk density of 0.8 g/cm³.

### I.1. Manufacture of Inventive TiO₂-Coated Redox-Active Material, PIG.2

A fluidized bed reactor with external heating jacket was charged with 60 g of C-PIG.1, and under an average pressure of 5 mbar C-PIG.1 was fluidized with N₂. The fluidized bed reactor was heated to 160° C. and kept at 160° C. for 2 hours (step (d.1)). To decrease filter congestion and aid in powder fluidization, the deposition encompassed regular reverse pulses of carrier gas alternating with pneumatic hammer impacts.

Step (a.1): In a vessel, Ti[OCH(CH₃)₂]₄(titanium tetra-isopropoxide, TTIP) was heated to 65 to 70° C.

TTIP in the gaseous state was introduced into the fluidized bed reactor through a sintered metal filter plate by opening a valve to a precursor reservoir that was charged with TTIP in liquid form and then kept at 65 to 70° C. in order to generate sufficient vapor pressure for the introduction into the fluidized bed reactor. The Ti precursor was diluted with nitrogen as carrier gas at 10 sccm. After a reaction period of 15 minutes non-reacted TTIP was removed through the N₂ stream, and the reactor was purged with N₂ at 30 sccm for 12 minutes.

Step (b.1): Then, ozone as an 8% by volume mixture with O₂ was introduced into the fluidized bed reactor by opening a valve to an ozone generator that produced ozone from oxygen. After a reaction period of 12 minutes non-reacted ozone was removed through the nitrogen stream, and the reactor was purged with nitrogen for another 12 minutes.

Step (c.1): The above sequence of (a.1) and (b.1) was repeated 40 times.

The reactor was then cooled to 25° C. and the material so obtained was discharged. The resultant PIG.2 displayed a bright yellow color as observed in C-PIG.1. A Ti-content of 0.98 wt % was determined by ICP-OES.

### I.2. Manufacture of Inventive TiO₂-Coated Redox-Active Material, PIG.3

Experiment I.1 was repeated but the sequence of (a.1) and (b.1) was repeated 80 times. The reactor was then cooled to 25° C. and the material so obtained was discharged. The resultant PIG.3 displayed a bright yellow color as observed in C-PIG.1. A Ti-content of 2.09 wt % was determined by ICP-OES.

### I.3. Manufacture of a Further Comparative Material, C-PIG.4

Experiment I.1 was repeated but in step (b.1) ozone was replaced by moisture. Water in the gaseous state was introduced into the fluidized bed reactor by opening a valve to a reservoir that contained liquid water kept at 25° C., with nitrogen as carrier gas with 10 sccm. After a reaction period of 60 seconds non-reacted water was removed through the N₂ stream, and the reactor was purged with N₂ at flow rate of 30 sccm for 12 min. The above sequence was repeated 10 times. The reactor was cooled to 25° C. and the material so obtained was discharged. Comparative material C-PIG.4 was obtained, which displayed an undesirable color change toward dark green. The determined Ti uptake from ICP-OES was 0.14 wt %.

### II. Coloristic Evaluations of Inventive TiO₂-Coated Redox-Active Materials PIG.2 and PIG.3

Coloristic evaluations and tests for resistance to degradation in alkaline solutions of 8%, 15% and 33% K₂CO₃ were performed. The results for inventive redox-active materials PIG.2 and PIG.3 were excellent, and were superior for PIG.3, when compared to C-PIG.1. On the other hand, C-PIG.4 exhibited undesirable color characteristics, even inferior to base material C-PIG.1.

### III. Cathode Active Material (CAM) as Redox-Active Material, CAM.1

### III.1. Synthesis of Redox-Active Material, CAM.1

The preparation of CAM.1 was carried out as follows. A stirred tank reactor was filled with deionized water. The precipitation of mixed transition metal hydroxide precursor was started by simultaneous feed of an aqueous transition metal solution and an alkaline precipitation agent at a flow rate ratio of 1.9, and a total flow rate resulting in a residence time of 8 hours. The aqueous transition metal solution contained Ni, Co and Mn at a molar ratio of 6:2:2 as sulfates each and a total transition metal concentration of 1.65 mol/kg. The alkaline precipitation agent consisted of 25 wt. % sodium hydroxide solution and 25 wt. % ammonia solution in a weight ratio of 25. The pH value was kept at 11.9 by separate feed of an aqueous sodium hydroxide solution. After stabilization of particle size the resulting suspension was removed continuously from the stirred vessel. The mixed transition metal (TM) oxyhydroxide precursor was obtained by filtration of the resulting suspension, washing with distilled water, drying at 120° C. in air and sieving.

The mixed TM oxyhydroxide precursor obtained was mixed with Al₂O₃ (average particle diameter 6 nm) and LiOH monohydrate to obtain a concentration of 0.3 mole-% Al relative to Ni+Co+Mn+Al and a Li/(TM+Al) molar ratio of 1.03. The mixture was heated to 885° C. and kept for 8 hours in a forced flow of oxygen to obtain CAM 1. D50=9.5 μm determined using the technique of laser diffraction in a Mastersize 3000 instrument from Malvern Instruments.

### III.2. Manufacture of Inventive Al₂O₃-Coated Redox-Active Material, CAM.2

A fluidized bed reactor with external heating jacket was charged with 100 g of CAM.1, and under an average pressure of 5 mbar CAM.1 was fluidized with N₂. The fluidized bed reactor was heated to 180° C. and kept at 180° C. for 3 h (step (d.2)).

Step (a.2): Trimethylaluminum in the gaseous state was introduced into the fluidized bed reactor through a filter plater by opening a valve to a precursor reservoir that contained the aluminum compound in liquid form and that was kept at 25° C. The trimethylaluminum was diluted with nitrogen as carrier gas at a flow rate of 10 sccm. After a reaction period of 210 seconds, non-reacted trimethylaluminum was removed through the nitrogen stream, and the reactor was purged with nitrogen for 15 minutes with a flow of nitrogen at 30 sccm.

Step (b.2): Then, ozone as an 8% by volume mixture with O₂ was introduced into the fluidized bed reactor by opening a valve to an ozone generator that produced ozone from oxygen. Said O₃/O₂ mixture is dosed into the fluidized bed reactor for 30 minutes after opening the dosing valve, while N₂ was kept flowing at 10 sccm. Subsequently, ozone was removed through the nitrogen stream, and the reactor was purged with nitrogen for another 25 minutes.

Step (c.2): The above sequence of (a.2) and (b.2) was repeated 4 times.

The reactor was then cooled to 25° C. and the material so obtained was discharged. The resultant CAM.2 displayed the following properties: D50=10.6 μm determined using the technique of laser diffraction in a Mastersize 3000 instrument from Malvern Instruments; total Al-content: 0.124 wt %, determined by ICP-OES.

### III.3. Manufacture of a Further Comparative Material, C-CAM.3

Experiment III.2 was repeated but in step (b.2) ozone was replaced by moisture. Water in the gaseous state was introduced into the fluidized bed reactor by opening a valve to a reservoir that contained liquid water kept at 25° C., with nitrogen as carrier gas with 10 sccm. After a reaction period of 120 seconds non-reacted water was removed through the N₂ stream, and the reactor was purged with N₂ at flow rate of 30 sccm for 15 min. The above sequence was repeated 4 times. The reactor was cooled to 25° C. and the material so obtained was discharged. Comparative material C-CAM.3 was obtained, which displayed the following properties:

D50=10.6 μm determined using the technique of laser diffraction in a Mastersize 3000 instrument from Malvern Instruments; total Al-content: 0.098 wt %, determined by ICP-OES.

### IV. Electrochemical Evaluation of Inventive Al₂O₃-Coated Redox-Active Material CAM.2

Electrochemical testing of the cathode active materials (CAM.1, CAM.2, CAM.3) were carried out in coin half-cells (vs. Li metal as anode material to an upper cut-off voltage of 4.3V vs. Li/Li⁺, 1M LiPF₆ in EC:EMC wt % as electrolyte (EC=ethylene carbonate, EMC=ethyl methyl carbonate), GF/D glass fiber separator (Whatman), and CR2032 from Hohsen Corp.) to obtain a 1^{st} cycle discharge capacity.

Inventive half-cell based upon CAM.2 was superior over comparative half-cells based upon CAM.1 or C-CAM.3.

1-13. (canceled)

14. A process for making an at least partially coated redox-active material, the process comprising:
(a) treating a redox-active material with an alkyl metal compound, to obtain a material, wherein the redox-active material comprises a metal selected from the group consisting of V, Cr, Mn, Fe, Co, Ni, Ag, Cu Mo, W, Sn, Sb, Te, Pb, Bi and rare earth metals in an oxidized state;
(b) treating the material obtained in (a) with an oxidizing agent; and
(c) repeating the sequence of (a) and (b) from 1 to 100 times,
wherein an average thickness of a resulting coating is in a range of from 0.1 to 50 nm.

15. The process of claim 14, wherein, in (a), the alkyl metal compound is dosed in diluted form using an inert gas.

16. The process of claim 14, wherein the alkyl metal compound is selected from the group consisting of alkyl metal compounds of Ti, Al, Zn, Hf, Si, or Zr.

17. The process of claim 14, wherein the alkyl metal compound is selected from the group consisting of Al(CH₃)₃, Al(C₂H₅)₃, triisobutyl aluminum, Zn(CH₃)₂, and Zn(C₂H₅)₂, and methyl alumoxane.

18. The process of claim 14, wherein the redox-active material in (a) comprises at least two different metals selected from the group consisting of V, Cr, Mn, Fe, Co, Ni, Ag, Cu, Mo, W, Sn, Sb, Te, Pb, Bi and rare earth metals in an oxidized state.

19. The process of claim 14, wherein the oxidizing agent in (b) is selected from the group consisting of species with a positive standard reduction potential E°≥0 V.

20. The process of claim 14, wherein the oxidizing agent in (b) is selected from the group consisting of ozone, oxygen and peroxides.

21. The process of claim 14, wherein, in (b), no humidity is applied.

22. The process of claim 14, which comprises (d) an additional thermal and/or chemical pre-treatment.

23. The process of claim 14, which comprises (e) an additional thermal and/or chemical post-treatment.

24. The process of claim 14, wherein (a) to (c), and optionally (d) an additional thermal and/or chemical pre-treatment and (e) an additional thermal and/or chemical post-treatment, are performed in a rotary kiln, a free fall mixer, a continuous vibrating bed or a fluidized bed.

25. The process of claim 14, wherein between each (a) and (b), and after (b), purging is performed.

26. The process of claim 14, wherein the redox-active material is an oxide.

27. The process of claim 14, wherein the redox-active material is a bismuth-based inorganic pigment, an iron-based magnetic powder, a TM-containing oxide catalyst, or a cathode active material of formula Li₁₊ₓTM₁₋ₓO₂, wherein TM is a combination of Ni, Co, and Mn, and x is in a range of from 0 to 0.2, and optionally comprises a metal selected from the group consisting of Al, Ti, Mo, W and Zr.
